(19) United States
(12) Patent Application Publication
(10) Pub. No.: US 2026/0213716 A1
(43) Pub. Date: Jul. 23, 2026

(54) ADAPTIVE DIGITAL LC COMPENSATION FILTER FOR AUDIO AMPLIFIERS

(71) Applicant: Axign B.V., Enschede (NL)

(72) Inventors: Christiaan Egidius LOKIN, Enschede (NL); Daniel SCHINKEL, Enschede (NL); Koen Theodorus RABEN, Enschede (NL)

(21) Appl. No.: 19/142,063

(22) PCT Filed: Dec. 13, 2023
(86) PCT No.: PCT/NL2023/050656

§ 371 Date: Jun. 20, 2025

(30) Foreign Application Priority Data
Dec. 21, 2022 (NL) 2033779

(51) Int. Cl. H03F 3/217; H03K 3/017

(52) U.S. Cl. CPC H03F 3/217; H03K 3/017; H03F 2200/03; H03F 2200/171

(57) ABSTRACT

The present invention is in the field of basic electronic circuitry, in particular for an audio amplifier, more in particular a class-D amplifier, such as for use in a digital audio converter and digital amplifier controller, a chip comprising said audio amplifier, and a device comprising said audio amplifier or said chip.

### FIELD OF THE INVENTION

The present invention is in the field of basic electronic circuitry, in particular for an audio amplifier, more in particular a class-D amplifier, such as for use in a digital audio converter and digital amplifier controller, a chip comprising said audio amplifier, and a device comprising said audio amplifier or said chip.

### BACKGROUND OF THE INVENTION

An audio power amplifier comprises basic electronic circuitry that amplifies low-power electronic audio signals that enter the circuitry, to a high enough power for driving a loudspeaker. Audio power amplifiers find many applications. The audio amplifier may be combined in a chain of electronic components or electronic circuits, each performing an individual task or contributing to a common task. Basically, any audio signal can be provided to the power amplifier, as is commonly done. The output signal of the audio amplifier power may be from a few watts to tens or hundreds of watts, and sometimes even a multitude thereof. Power amplifiers are typically integrated in a (final) product or integrated circuit.

Design parameters for audio power amplifiers are amongst others frequency response, gain, noise, and distortion, which parameters are typically interdependent.

A Class-D amplifier is typically used in modern consumer electronics audio products, bass amplifiers and sound reinforcement system gear. Amplifiers may comprise filters, pre-amplifiers, power output stages and the like. An audio filter is typically a frequency dependent circuit. It is designed to operate in a specific audio frequency range. It is noted that a human hearing range is commonly considered to run from 20 to 20,000 Hz. There is however a considerable variation between individuals, especially at high frequencies. Also, typically there is a gradual loss of sensitivity to higher frequencies with age. In addition, sensitivity to specific frequencies may also vary with said frequency. The audio frequency range typically used in audio amplifiers therefore runs from about 20 Hz to 20 kHz, and sometimes to 40 kHz or even 80 kHz. Audio filters are designed to amplify, pass, or attenuate specific frequency ranges. Many types of filters exist, for instance low-pass filters, high-pass filters, band pass filters, all-pass filters affecting a phase of a given frequency component, a magnitude, etc.

In class-D amplifiers with feedback after the LC output filter stability of the total loop is considered to be required. The stability may be endangered when the LC output filter deviates from its intended functioning. A solution is a method for automatic gain calibration with a pilot tone in a digital audio amplifier with a feedback ADC. An illustrative schematic is given in FIG. 1. The pilot tone is generated at the desired 0 dB crossing frequency (e.g. 150 kHz) of the open loop. By comparing the magnitude of the pilot tone before and after the plant that is being controlled (which includes the LC filter), the gain at the desired frequency is obtained. If this gain differs from 0 dB the gain of the digital loop is adjusted, creating a control loop which regulates the 0 dB crossing to be at the desired frequency. By adjusting the gain loop stability can be achieved even when the loop characteristics start to deviate over time. In an alternative adaptive inverse control from a control theory perspective may be used. The goal therein is to adjust a dynamic behavior of an unknown plant of the loop by adding an adaptive filter in the loop, sequentially following the unknown plant. The adaptive filter is regulated in order to match a transfer of a mathematical/electronic product of the unknown plant and the adaptive loop filter to that of the reference path in the loop.

However, prior art amplifier loops may have stability issues, such as due to unknown deviations in the LC output filter. These deviations can originate from, among other causes, production spread, aging effects, temperature or voltage/current dependencies. And even when a feedback loop is used, such a feedback loop may be used to control a plant which has too much inherent phase shift, and therefore is not well suited. In an approach a static (lead-lag) compensator nay be placed in the feedback loop to compensate the inherent phase shift of the plant in a nominal case; however, this is a sub-optimal solution therefore. Further, it is noted that deviations that can occur in the plant may be significant enough, such that the static compensator is not sufficient for loop stability.

Incidentally reference can be made to Mostert et al., US 2009/102557 A1, and EP 3 525 343B1 , which documents are considered background art. Mostert et al. (DOI: 10.1109/ISSCC.2017.7870273) present a 5-channel Class-D amplifier with integrated low-latency delta-sigma (ΔΣ) ADCs, each consuming only 30 mW, for digital feedback after the output filter. With this system, more than 50 dB loop-gain is obtained. THD+N is 0.004% over the full audio band, which is at least 10× better than prior art at that point in time, where data is only given at 1 kHz.

It is an objective of the present invention to overcome disadvantages of the prior art audio amplifiers without jeopardizing functionality and advantages.

### SUMMARY OF THE INVENTION

The present invention relates in a first aspect to an audio amplifier 100, in particular a class-D amplifier, comprising a signal loop 90, the loop comprising an audio amplifier input 10 for receiving a to be amplified signal 91, the input in connection 92 with at least one compensator 21, in particular at least one digital compensator, more in particular at least one LC and low latency ADC compensator, the at least one compensator configured for compensating a transmission of audio output 96 and of ADC 60 input, the at least one compensator in connection 93 with at least one Pulse-Width-Modulator 40, the at least one pulse width modulator in connection 94 with a power stage 70, the power stage in connection 95 with at least one LC filter and load 80, the LC load configured to be in connection with an audio output 96, such as a speaker, the LC filter in connection 97 with at least one ADC 60, in particular a low latency ADC, the at least one ADC in connection 98 with the at least one LC and low latency ADC compensator, characterized in at least one adaptive digital LC compensation filter 200, the adaptive digital LC compensation filter 200 configured to receive as first input 201 output from the LLADC 60 and to receive as second input 202 output from the Pulse-Width-Modulator and to provide output 203 to the compensator 21, the adaptive digital LC compensation filter 200 comprising a feed stream multiplier 220, wherein the feed stream multiplier 220 is configured to transfer updated weights w₁-wₘ to a compensator 21, the output 203 comprising the updated weights w₁-wₘ, and wherein the adaptive digital LC compensation filter is therewith configured to stabilize a performance of the loop. The term “at least one” indicates that more than one element as indicated by the at least one may be present, such as in a case of parallel and/or serial audio amplifiers or part thereof, or combination thereof. FIG. 4 for instance shows parallel PWM's and parallel loop filters, amongst others. Therewith, amongst others, stability issues that can occur in the amplifier loop because of unknown deviations in the LC output filter are solved. Presented is an adaptive compensation filter that uses digital bitstreams from the PWM generator and the feedback Low-Latency ADC (LLADC) to update the coefficients such that LC filter deviations are compensated for. As a starting point for the adaptive filter a copy of the compensation filter for the LLADC may be used. By combining e.g. three feed outs of this 2-pole compensation filter with adjustable weights, a transfer is created that converges to the inverse of the LC filter, load and LLADC. The compensation filter in the amplifier loop can then be updated, increasing the effectiveness of the LC&LLADC compensation. By choosing the LLADC compensation filter with multiple feed outs as starting point for the adaptive LC&LLADC compensation filter, a significant reduction of coefficient sensitivity is obtained with respect to a more general tapped delay line approach. With an adaptive compensation filter the deviations in the plant can be compensated for, but a generic adaptive filter often has a high coefficient sensitivity due to the numerical stiffness of the problem. The compensator 21 typically comprises the inverted frequency transfer of the LLADC 60, in particular of the zeros thereof, and the poles of the LC filter 80. The inversion of these dynamics effectively cancels the effect of the LLADC and LC filter in the feedback loop, simplifying the design of the loop filter. Mathematically the transfer function A of LC filter 80 and transfer function B of LLADC 60 is compensated by compensator 21 by 1/(A*B). Since the LC filter is indeed influenced by production spread, there will always be a deviation between the actual LC filter component values, and the compensation filter. The loop filter is initially designed with this spread in mind as such to be stable over a range of this spread in component values. After enabling the ‘Adaptation’ the LC compensation converges to the optimal values, and in turn a more aggressive loop filter can be instantiated. An exemplary solution to this coefficient sensitivity problem is to choose a fixed pre-filter with multiple feed outs, such that the coefficients, on which are adapted, have low coefficient sensitivity. In an exemplary embodiment, with reference to FIG. 3, the present adaptive digital LC compensation filter increases robustness of e.g. class-D amplifiers, with post output filter feedback by the following steps. These steps are also annotated in FIG. 3, having the same numbering as the steps below:
1. Filtering the LLADC bitstream with the LLADC compensation filter with multiple feed outs. By summing/subtracting different combinations of the feed outs three prefilters are obtained: One with a low-pass characteristic (a), one with a band-pass characteristic (b) and one with a high-pass characteristic (c). By using this technique three (almost) orthogonal feed outs are constructed.
2. Multiplying the three feed out streams with three separate weights.
3. Adding the three weight-multiplied streams to create one signal
4. Subtracting this combined signal from the PWM bitstream which is used as reference signal, creating an error signal.
5. Multiplying the error signal with a convergence factor mu.
6. Compute a new value for the weights dependent on the previous weight, the total error and the signal value of the corresponding feed out.
7. Adjust the LC & LLADC compensation filter in the amplifier loop.

The present one adaptive digital LC compensation filter provides a higher robustness to spread in the LC output filter, and therefore cheaper components in the output filter may be used, reducing costs. Additionally, creating a more stable loop might give opportunities to improve the noise and distortion performance of the system, by using a more aggressive loop filter.

The phrase “stabilization of the performance of the loop” is considered to be a functional feature, relating to a technical effect obtained by the present adaptive digital LC compensation filter as a consequence of the build up of the filter.

In a second aspect the present invention relates to a signal loop 90 for an audio amplifier, the loop comprising an audio amplifier input 10 for receiving a to be amplified signal 91, the input in connection 92 with at least one compensator 21, in particular at least one digital compensator, more in particular at least one LC and low latency ADC compensator, the at least one compensator configured for compensating a transmission of audio output 96 and of ADC 60 input, the at least one compensator in connection 93 with at least one Pulse-Width-Modulator 40, the at least one pulse width modulator in connection 94 with a power stage 70, the power stage in connection 95 with at least one LC filter and load 80, the LC load configured to be in connection with an audio output 96, such as a speaker, the LC filter in connection 97 with at least one ADC 60, in particular a low latency ADC, the at least one ADC in connection 98 with the at least one LC and low latency ADC compensator, characterized in at least one adaptive digital LC compensation filter 200, the adaptive digital LC compensation filter 200 configured to receive as first input 201 output from the LLADC 60 and to receive as second input 202 output from the Pulse-Width-Modulator and to provide output 203 to the compensator 21, the adaptive digital LC compensation filter 200 comprising a feed stream multiplier 220, wherein the feed stream multiplier 220 is configured to transfer updated weights w1-wm, to a compensator 21, the output 203 comprising the updated weights w1-wm, and wherein the adaptive digital LC compensation filter is therewith configured to stabilize a performance of the loop.

In a third aspect the present invention relates to an adaptive digital LC compensation filter 200 for a feedback loop, configured to receive input 201 from an ADC 60 and input 202 from the at least one Pulse-Width-Modulator and to provide output 203 to at least one compensator 21, and wherein the adaptive digital LC compensation filter 200 configured to receive as first input 201 output from the LLADC 60 and to receive as second input 202 output from the Pulse-Width-Modulator and to provide output 203 to the compensator 21, the adaptive digital LC compensation filter 200 comprising a feed stream multiplier 220, wherein the feed stream multiplier 220 is configured to transfer updated weights w1-wm, to a compensator 21, the output 203 comprising the updated weights w1-wm, and wherein the adaptive digital LC compensation filter is therewith configured to stabilize a performance of the loop.

In a fourth aspect the present invention relates to an integrated circuit comprising the audio amplifier or the at least one adaptive digital LC compensation filter or the signal loop according to the invention.

In a fourth aspect the present invention relates to an electronic device comprising an integrated circuit according to the invention, or an adaptive digital LC compensation filter according to the invention, or the signal loop according to the invention, such as an audio amplifier, an active loud-speaker system, an active noise reduction system, a high-speed closed loop controller, a high resolution low latency data converter, an A/D converter, a power supply controller, a motor controller, a digital audio converter, a digital amplifier controller, and combinations thereof.

Thereby the present invention provides a solution to one or more of the above mentioned problems.

Advantages of the present description are detailed throughout the description.

### DETAILED DESCRIPTION OF THE INVENTION

The present invention relates in a first aspect to an audio amplifier, in particular a class-D amplifier, comprising a signal loop.

In an exemplary embodiment of the present audio amplifier the at least one adaptive digital LC compensation filter 200 comprises a second low-latency ADC compensator 210 in multiple feed stream connection with at least one feed stream multiplier 220, the at least one feed stream multiplier configured to multiply the multiple feed streams independently with separate weights w₁-wₘ, in particular wherein m=3, wherein the multiplied multiple feed streams are configured to be provided to a weight adder 230, wherein the weight adder is configured to provide added, weight multiplied feed streams to a first subtractor 240, wherein the first subtractor is configured to subtract added, weight multiplied feed streams from the input from the at least one Pulse-Width-Modulator and to provide an error signal to the at least one feed stream multiplier 220 in order to update weights w₁-wₘ, wherein the at least one feed stream multiplier 220 is configured to transfer updated weights w₁-wₘ, to the at least one compensator 21.

In an exemplary embodiment of the present audio amplifier the at least one adaptive digital LC compensation filter 200 comprises an error signal multiplier 250, in particular an error signal multiplier configured to multiply the error signal with a convergence factor mu therewith providing a total error signal.

In an exemplary embodiment of the present audio amplifier the at least one adaptive digital LC compensation filter 200 comprises a weight corrector 260 configured to multiply the multiplied error signal of the error signal multiplier 250 with a signal value of a corresponding feed stream of the second low-latency ADC compensator 210 therewith providing a weight correction and to adapt the separate weights w₁-wₘ at t=n in view of the separate weight values at t=n and the weight correction and to obtain separate weights w₁-wₘ at t=n+1, in particular wherein the weight corrector 260 is configured to multiply the multiplied error signal at a clock frequency or a partial frequency thereof.

In an exemplary embodiment of the present audio amplifier a clock frequency of the present audio amplifier is in the order of 10-100 kHz, such as 48 kHz, and likewise a frequency of operation of a loop filter is a multitude thereof, typically a 2^{m} multitude thereof, typically wherein m∈[6,12], in particular wherein m∈[8,10], such as m=9, and likewise a frequency of operation of a LC compensation filter is also a multitude thereof, typically a 2^{p} multitude thereof, typically wherein p∈[1,10], in particular wherein p∈[2,6], such as p=3 or 4.

In an exemplary embodiment of the present audio amplifier second low-latency ADC compensator 210 is configured to operate at a partial frequency of the at least one compensator 21, in particular at a 1/n frequency thereof, wherein n∈[2,100], more in particular wherein n∈[4,64], more in particular wherein n∈[4,64], even more in particular n∈[16,64], such as wherein n∈[2³, 2⁴, 2⁵, 2⁶].

In an exemplary embodiment of the present audio amplifier second low-latency ADC compensator 210 is configured to form a copy of the LLADC compensation part of the at least one compensator 21.

In an exemplary embodiment of the present audio amplifier the signal value of a corresponding feed stream of the second low-latency ADC compensator 210 each individually has a different frequency shape, in particular substantially orthogonal shapes, more in particular wherein the frequency shape is selected from low pass LP, band pass BP, and high pass HP.

In an exemplary embodiment of the present audio amplifier the at least one adaptive digital LC compensation filter 200 is configured to add 230 and to subtract the at least two feed out streams of the second low-latency ADC compensator 210 to form a combination of said at least two feed out streams with substantially orthogonal frequency shapes respectively.

In an exemplary embodiment the present audio amplifier comprises a loop filter 22 in connection with the at least one compensator 21 and the PWM 40.

In an exemplary embodiment of the present audio amplifier comprises a weight w₁-wₘ updater 270 in output connection with the at least one compensator 21 and in input connection with the weight corrector 260, wherein the weight updater is configured digitally to accumulate a weight w₁-wₘ at t=n+1 in view of the weight at t=n.

In an exemplary embodiment of the present audio amplifier the PWM controller 100 comprises in series (i) at least two parallel loop filters 20 for loop-gain and signal processing, preferably at least four loop filters, each loop filter comprising multiple inputs 10, 15 and at least one output 25, wherein a loop filter 20 is adapted to perform at least one of interpolation of the pulse code modulated PCM input signal, common mode control, differential mode control, audio processing, audio filtering, audio emphasizing, and LC compensation, characterized in that each single output 25 being in electrical connection with (ii) at least one butterfly mixer 30, the butterfly mixer being capable of mixing at least two inputs 25 and of providing at least two mixed outputs 35 to (iii) at least two parallel pulse width modulators PWM's 40, wherein a pulse width modulator 40 comprises a carrier signal with an adaptable and programmable shape, phase and frequency, wherein the carrier signal is compared by the pulse width modulator with the input signal 35 to create an output signal 45, wherein (iv) loop filters, butterfly mixer, and PWM's are individually and independently programmable and adaptable, wherein loop filter input 15 is adapted to receive at least one of a local digital PWM processed output signal 45, and an ADC output, and comprising at least one setting data storage means for loading, adapting and storing programmable and adaptable settings, and optionally wherein the loop filter 20 comprises at least 3, preferably at least 5, more preferably at least 8 filter stages, and/or wherein each stage comprises at least one of a an input having at least one coefficient, b a feedback coefficient, c a feed forward coefficient, d an adder, e an output having at least one coefficient, and f a register comprising a processed signal, and/or comprising at least one data storage means capable of storing at least one of a clipping level, and a zero detection, wherein clipping level and zero detection of the stored signal are individually and independently programmable, and/or wherein the butterfly mixer 30 comprises at least two stages, wherein in an initial stage outputs 25 of two loop filters are mixed forming a mixed initial stage output, and wherein in a further stage outputs of two mixed previous stages are mixed forming a mixed further stage output 35, and/or wherein the butterfly mixer 30 comprises at least three or more stages, and/or wherein a carrier signal of a first channel is programmed to be phase synchronous and/or frequency synchronous with a carrier signal of another channel, and/or wherein a carrier signal is disabled to leave a channel “free running” without enforcing fixed-frequency PWM, and/or comprising at least one digital input interface adapted to read-in pulse code modulated PCM digital signals and thereby providing input 10 to the loop filters 20, typically one PCM per loop filter, and/or further comprising at least one analog to digital converter ADC for converting an analog signal into a digital signal, typically one ADC per loop filter, and/or wherein the PWM's 40 provide output 45 to at least one crossbar 50, the cross-bar comprising at least two outputs 55, preferably at least four outputs, a number of outputs typically being equal to the number of PWM signals 55, and/or wherein the crossbar is adapted to permute at least two outputs 55, and/or comprising at least one adaptable and programmable linear ramp generator with feed-in coefficients, for at least one of input volume control, controlling crossfading typically between feedback signals, and gradual application of DC offset, and/or comprising a subsequent processor for at least one of interpolation of a PCM-input signal, and decimation of a loop-filter output signal, and/or comprising a pre-filter for reducing high-frequency quantization noise in feed-back signals to the loop-filter 15. Exemplary embodiments of such PWMs, details thereof, and advantages thereof, may be found in WO 2017/179974 A1 of the present applicant, which document and its contents are incorporated by reference.

The invention although described in detailed explanatory context may be best understood in conjunction with the accompanying examples and figures.

### SUMMARY OF FIGURES

FIG. 1: Prior art Adaptive Gain Control with Pilot Tone.

FIG. 2: Schematic of Adaptive Digital LC Compensation Concept

FIG. 3: Detailed Schematic of Adaptive Digital LC Compensation Concept

FIG. 4: Exemplary PWM

### DETAILED DESCRIPTION OF FIGURES

The figures are of an exemplary nature. Elements of the figures may be combined. In the figures:
10 input (digital)
15 PWM and ADC feedback signals
20 programmable loop filter, e.g. the present filter
21 LC+LLADC Compensation
22 loop filter
25 output signal loop filter
30 butterfly mixer
35 output signal butterfly mixer/PWM input
40 pulse width modulator (PWM)
45 PWM output signal
50 crossbar
55 controller output signals
60 LLADC
70 power stage
80 LC filter & load
90 signal loop
91 signal input
92 LLADC output
93 PWM input
94 power stage input
95 LC filter input
96 audio output
97 ADC input
98 ADC output
100 audio amplifier
200 adaptive digital LC compensation filter
201 ADC compensation input
202 PWM output
203 LC compensator weight output
210 LLADC compensation filter
211 state mixer
220 feed stream multiplier
230 weight adder
240 first subtractor
250 error signal multiplier
260 weight corrector
270 weight updater

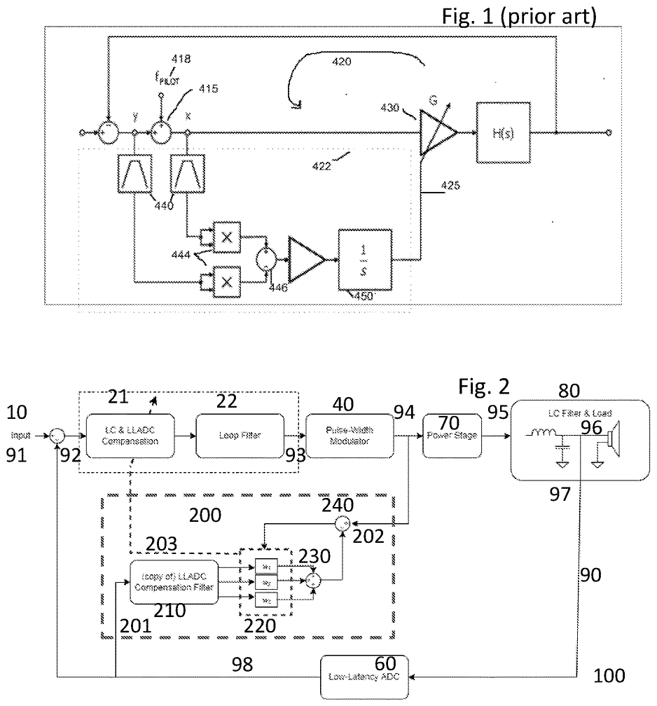

FIG. 1: Prior art Adaptive Gain Control with Pilot Tone.

FIG. 2: Schematic of Adaptive Digital LC Compensation Concept. From FIG. 2 it follows that the LC filter and Load 80 are in connection with the audio output.

The multiple feed streams (three in the example in FIG. 2) are constructed by making for instance a combination of the input to and the filter states in the (copy of) LLADC Compensation filter. A way of choosing the combination in the example, is to receive low-pass, band-pass and high-pass output signals at the output as they have dominant components in different frequency band, this aids with convergence of the weights.

FIG. 2 shows that the loop filter 22 receives input from the compensator 21 and provides output to the PWM 40.

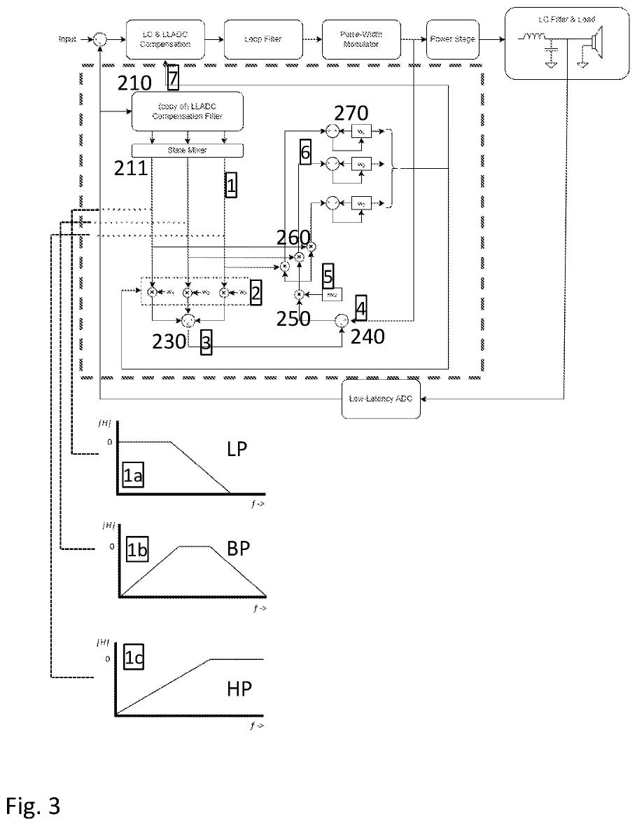

FIG. 3: Detailed Schematic of Adaptive Digital LC Compensation Concept

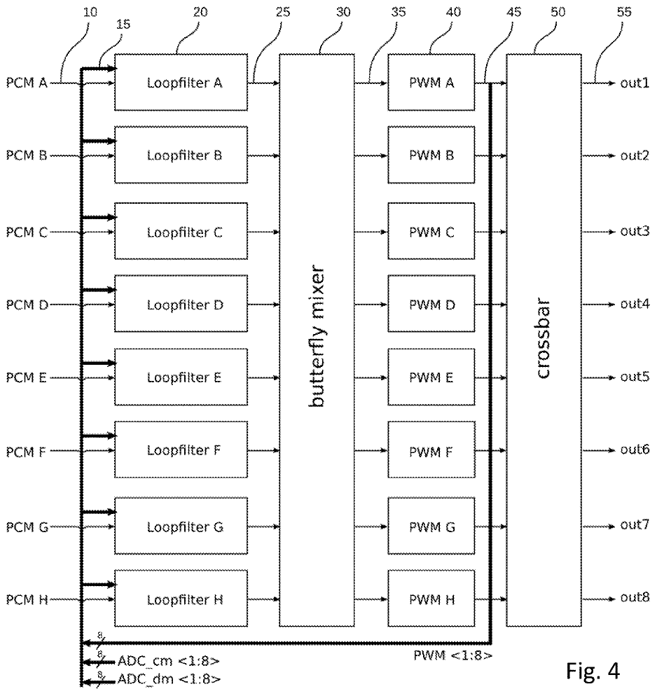

FIG. 4: Exemplary PWM

Details of the figures and advantages of the embodiments disclosed therein are given throughout the description.

1-13. (canceled)

14. An audio amplifier, comprising a signal loop, the signal loop comprising
an audio amplifier input, configured to receive a to be amplified signal, the audio amplifier input in connection with
at least one compensator, configured to compensate a transmission of an audio output and of an ADC input, wherein the at least one compensator is in connection with
at least one Pulse-Width-Modulator (PWM in connection with
a power stage in connection with
at least one LC filter and load, wherein the LC filter load is configured to be in connection with the audio output, and is in connection with
at least one ADC, in connection with the at least one compensator, and
characterized in
at least one adaptive digital LC compensation filter configured to receive an input from the ADC and an input from the at least one Pulse-Width-Modulator, and to provide an output to the at least one compensator, and wherein the at least one adaptive digital LC compensation filter is configured to stabilize a performance of the loop.

15. The audio amplifier according to claim 14, wherein the at least one adaptive digital LC compensation filter comprises a low-latency ADC compensator in connection with at least one feed stream multiplier, the at least one feed stream multiplier is configured to multiply multiple feed streams independently with a separate weight between w₁-wₘ, wherein multiplied multiple feed streams are configured to be provided to a weight adder, wherein the weight adder is configured to provide added weights to a first subtractor, wherein the first subtractor is configured to subtract added weights from the input from the at least one Pulse-Width-Modulator and to provide an error signal to the at least one feed stream multiplier in order to update the weights w₁-wₘ, wherein the at least one feed stream multiplier is configured to transfer updated weights w₁-wₘ, to the at least one compensator.

16. The audio amplifier according to claim 15, wherein the at least one adaptive digital LC compensation filter comprises an error signal multiplier, configured to multiply the error signal with a convergence factor, to provide a total error signal.

17. The audio amplifier according to claim 16, wherein the at least one adaptive digital LC compensation filter comprises a weight corrector, configured to multiply the total error signal with a signal value of a corresponding feed stream of the low-latency ADC compensator, to provide a weight correction and to adapt the separate weights w₁-wₘ at t=n in view of the separate weight values att=n and the weight correction and to obtain separate weights w₁-wₘ att=n+1.

18. The audio amplifier according to claim 17, wherein the low-latency ADC compensator is configured to operate at a partial frequency of the at least one compensator, wherein n∈[2,100], and
wherein the low-latency ADC compensator is configured to form a copy of the low-latency ADC compensation part of the at least one compensator, and
wherein a clock frequency is in the order of 10-100 kHz, and
wherein a frequency of operation of a loop filter is a multitude of the clock frequency, and/or
wherein a frequency of operation of a LC compensation filter is a multitude of the clock frequency.

19. The audio amplifier according to claim 17, wherein the signal value of a corresponding feed stream of the second low-latency ADC compensator each individually has a different frequency shape.

20. The audio amplifier according to claim 19, wherein the at least one adaptive digital LC compensation filter is configured to add to subtract at least two feed out streams of the low-latency ADC compensator to form a combination of said at least two feed out streams with substantially orthogonal frequency shapes respectively.

21. The audio amplifier according to claim 14, further comprising a loop filter in connection with the at least one compensator and the PWM.

22. The audio amplifier according to claim 16, further comprising a weight w₁-wₘ updater in output connection with the at least one compensator and in input connection with the weight corrector, wherein the weight updater is configured to digitally accumulate a weight w₁-wₘ at t=n+1 in view of the weight at t=n.

23. The audio amplifier according to claim 14, wherein the PWM comprises in series
(i) at least two parallel loop filters for loop-gain and signal processing, each loop filter comprising multiple inputs and at least one output, wherein each loop filter is adapted to perform at least one of interpolation of a pulse code modulated (PCM) input signal, common mode control, differential mode control, audio processing, audio filtering, audio emphasizing, and LC compensation, and the one output of each loop filter is
in electrical connection with
(ii) at least one butterfly mixer, the butterfly mixer being capable of mixing at least two inputs and of providing at least two mixed outputs to
(iii) at least two parallel pulse width modulators (PWM's), wherein each pulse width modulator comprises a carrier signal with an adaptable and programmable shape, phase and frequency, and wherein the carrier signal is compared by the pulse width modulator with the mixed signal to create an output signal,
wherein the loop filters, the butterfly mixer, and the PWMs are individually and independently programmable and adaptable; and
wherein the loop filter input is adapted to receive at least one of a local digital PWM processed output signal, and an ADC output, and
comprises at least one setting data storage means for loading, adapting and storing programmable and adaptable settings.

24. A signal loop for an audio amplifier comprising an audio amplifier input configured to receive a to be amplified signal, the audio amplifier input in connection with
at least one compensator, configured to compensate for a transmission of an audio output and of an ADC input, the at least one compensator in connection with
at least one Pulse-Width-Modulator (PWM), the at least one pulse width modulator in connection with
a power stage in connection with
at least one LC filter and load, wherein the LC load is configured to be in connection with the audio output, and the LC filter is in connection with
at least one ADC, in connection with the at least one compensator, and
at least one adaptive digital LC compensation filter configured to receive an input from the ADC and an input from the at least one Pulse-Width-Modulator, and to provide an output to the at least one compensator, and wherein the at least one adaptive digital LC compensation filter is configured to stabilize a performance of the loop.

25. An integrated circuit comprising wherein the signal loop comprises:
an audio amplifier input, configured to receive a to be amplified signal, the audio amplifier input in connection with
at least one compensator, configured to compensate a transmission of an audio output and of an ADC input, the at least one compensator in connection with
at least one Pulse-Width-Modulator (PWM), in connection with
a power stage, in connection with
at least one LC filter and load, wherein the LC filter is configured to be in connection with the audio output, and is in connection with
at least one ADC, in connection with the at least one compensator; and
at least one adaptive digital LC compensation filter, configured to receive an input from the ADC and an input from the at least one Pulse-Width-Modulator, and to provide an output to the at least one compensator, and wherein the at least one adaptive digital LC compensation filter is configured to stabilize a performance of the loop.

26. An electronic device comprising an audio amplifier having a signal loop, wherein the signal loop comprises:
an audio amplifier input configured to receive a to be amplified signal, the audio amplifier input in connection with
at least one compensator, configured to compensate a transmission of an audio output and of an ADC input, the at least one compensator in connection with at least one Pulse-Width-Modulator (PWM), in connection with a power stage, in connection with
at least one LC filter and load, wherein the LC filter is configured to be in connection with the audio output, and is in connection with at least one ADC, in connection with the at least one compensator; and
at least one adaptive digital LC compensation filter, configured to receive an input from the ADC and an input from the at least one Pulse-Width-Modulator, and to provide an output to the at least one compensator, and wherein the at least one adaptive digital LC compensation filter is configured to stabilize a performance of the loop.

27. The audio amplifier according to claim 14, wherein the amplifier comprises a class D amplifier, the at least one compensator comprises at least one digital compensator.

28. The audio amplifier according to claim 19, wherein the frequency shapes are substantially orthogonal shapes.

29. The signal loop according to claim 24, wherein the PWM comprises in series:
(i) at least two parallel loop filters for loop-gain and signal processing, each loop filter comprising multiple inputs and at least one output, wherein each loop filter is adapted to perform at least one of interpolation of a pulse code modulated (PCM) input signal, common mode control, differential mode control, audio processing, audio filtering, audio emphasizing, and LC compensation, and the one output of each loop filter is in electrical connection with
(ii) at least one butterfly mixer, capable of mixing at least two inputs and of providing at least two mixed outputs to
(iii) at least two parallel pulse width modulators (PWMs), wherein each pulse width modulator comprises a carrier signal with an adaptable and programmable shape, phase and frequency, and wherein the carrier signal is compared by the pulse width modulator with the mixed signal to create an output signal;
wherein the loop filters, the butterfly mixer, and the PWMs are individually and independently programmable and adaptable; and
wherein the loop filter input is adapted to receive at least one of a local digital PWM processed output signal, and an ADC output, and comprises at least one setting data storage means for loading, adapting and storing programmable and adaptable settings

30. The signal loop according to claim 24, wherein the at least one adaptive digital LC compensation filter comprises:
a low-latency ADC compensator in connection with at least one feed stream multiplier, and wherein the at least one feed stream multiplier is configured to multiply multiple feed streams independently with a separate weight between w1-wm, to provide multiplied multiple feed streams;
a weight adder, configured to receive the multiplied multiple feed streams, and to provide added weights; and
a first subtractor, configured to subtract added weights from the input from the at least one Pulse-Width-Modulator and to provide an error signal to the at least one feed stream multiplier, to update the weights w1-wm.

31. The signal loop according to claim 30, wherein the at least one adaptive digital LC compensation filter further comprises:
an error signal multiplier, configured to multiply the error signal with a convergence factor to provide a total error signal.

32. The signal loop according to claim 31, wherein the at least one adaptive digital LC compensation filter further comprises:
a weight corrector, configured to multiply the total error signal with a signal value of a corresponding feed stream of the low-latency ADC compensator, to provide a weight correction and to adapt the separate weights w1-wm at t=n in view of the separate weight values at t=n and the weight correction and to obtain separate weights w1-wm at t=n+1.

33. The integrated circuit according to claim 25, wherein the PWM comprises in series:
(i) at least two parallel loop filters for loop-gain and signal processing, each loop filter comprising multiple inputs and at least one output, wherein each loop filter is adapted to perform at least one of interpolation of a pulse code modulated (PCM) input signal, common mode control, differential mode control, audio processing, audio filtering, audio emphasizing, and LC compensation, and the one output of each loop filter is in electrical connection with
(ii) at least one butterfly mixer, capable of mixing at least two inputs and of providing at least two mixed outputs to
(iii) at least two parallel pulse width modulators (PWMs), wherein each pulse width modulator comprises a carrier signal with an adaptable and programmable shape, phase and frequency, and wherein the carrier signal is compared by the pulse width modulator with the mixed signal to create an output signal;
wherein the loop filters, the butterfly mixer, and the PWMs are individually and independently programmable and adaptable; and
wherein the loop filter input is adapted to receive at least one of a local digital PWM processed output signal, and an ADC output, and comprises at least one setting data storage means for loading, adapting and storing programmable and adaptable settings.
